(19) United States
(12) Patent Application Publication
(10) Pub. No.: US 2007/0237277 A1
(43) Pub. Date: Oct. 11, 2007

(54) Method and Integrated Circuit for Controlling an Oscillator Signal

(76) Inventor: Reinhold Unterricker, Vaterstetten (DE)

Correspondence Address: BAKER BOTTS, L.L.P., 98 SAN JACINTO BLVD., SUITE 1500, AUSTIN, TX, 78701-4039, US

(21) Appl. No.: 11/279,036

(22) Filed: Apr. 7, 2006

(51) Int. Cl. H03D 3/24

(52) U.S. Cl. 375/375

(57) ABSTRACT

An integrated circuit is provided. The integrated circuit includes a delay locked loop comprising a binary phase detector which generates a binary phase detector signal, and a decimator receiving the binary phase detector signal, wherein the decimator generates the phase difference signal.

### TECHNICAL FIELD

The present invention generally relates to the field of integrated circuits within electronic devices and more specifically to controlling signals.

### BACKGROUND

Clock generators are key components in a variety of mobile devices. Phase-locked loops (PLL) are one type of clock generators which are mainly used in processors, memory units or other circuits where consistent clock signals are necessary.

A PLL usually contains a phase detector, a loop filter and a voltage-controlled oscillator, for instance. Phase detectors are components of a PLL and are commonly known in the art. In the following, the principle of a phase detector is described. The phase detector is a device that compares two input signals which may be represented by their specific phase and frequency, generating an output that is a measure of their phase difference (if, for example, they differ in frequency, it provides a periodic output at that frequency which is equal to the difference of the input frequencies). One of the above-mentioned frequencies corresponds to a reference value and the other one is the frequency or signal, which has to be controlled or set. If the phase of the reference frequency differs from the phase of the oscillator signal, the phase detector unit generates a phase-error signal. The phase-error signal may be processed and/or amplified and it will be used as an input or control signal for the oscillator of the PLL. Accordingly, the oscillator causes that its own phase will deviate in the direction of the phase of the reference signal. Thus, control of the oscillator phase and consequently its frequency is achieved and a fixed relationship between the phase and frequency of the reference signal and the oscillator signal is achieved.

### SUMMARY

According to an embodiment of the present invention a circuit generating a phase difference signal between a reference signal and an oscillator signal is provided. The circuit comprises a delay locked loop. The delay locked loop comprises a binary phase detector, which generates a binary phase detector signal. The further circuit comprises a decimator receiving the binary phase detector signal, wherein the decimator generates the phase difference signal.

According to an embodiment of the present invention, an integrated circuit is provided. The integrated circuit comprises a linear phase detector receiving a reference signal and an oscillator signal. The linear phase detector generates a phase relationship signal based on the reference signal and the oscillator signal. Further, the integrated circuit comprises a digital loop filter receiving the phase relationship signal and generating a digital control signal and a digital controlled oscillator receiving said digital control signal and generating the oscillator signal.

According to an embodiment of the present invention a method for controlling an oscillator signal with an integrated circuit is provided. The method comprises receiving a reference signal and an oscillator signal, generating a phase relationship signal based on the reference signal and the oscillator signal, filtering the generated phase relationship signal to produce a filtered phase relationship signal and generating an oscillator signal using the filtered signal.

Advantages and details of the present invention will become apparent to the reader of the present invention when reading the detailed description referring to preferred embodiments of the present invention, based on which the inventive concept is easily understandable.

Throughout the detailed description and the accompanying drawings same or similar components, units or devices will be referenced by same reference numerals for clarity purposes.

### BRIEF DESCRIPTION OF THE DRAWINGS

The accompanying drawings are included to provide a further understanding of the invention, and are incorporated in and constitute a part of this specification. The drawings illustrate embodiments of the present invention and together with the description serve to explain the principles of the invention. In the drawings,

FIG. 1 is a schematic view illustrating one embodiment of an integrated circuit according to this invention;

FIG. 1a is an embodiment of a linear digital phase detector;

FIG. 1b is an embodiment of a linear phase detector comprising a digital low pass filter;

FIG. 2 shows an embodiment of the loop element;

FIG. 3 shows an embodiment of the digital loop filter unit DLU;

FIG. 4 is a conventional PLL circuit; and

FIG. 5 shows an embodiment of the digital filter structure.

Reference will be made in detail to the embodiments of the invention examples, which are illustrated in the accompanying drawings. The following description relates to various embodiments based on which one skilled in the art will understand the invention. Nevertheless, one skilled in the art, will appreciate that the invention is likewise applicable to further embodiments, which are covered by the scope of the accompanying claims.

### DETAILED DESCRIPTION

Phase detectors are components of a PLL and several PLL architectures having different components are known. However, the main objective of a phase detector is to detect phase differences between two signals.

In general a phase detector will receive a reference signal and a local signal, and the output of the phase detector will provide a signal or signals corresponding to phase differences between the reference signal and the local signal. The local signal may correspond to an oscillator signal or a voltage controlled oscillator (VCO) respectively.

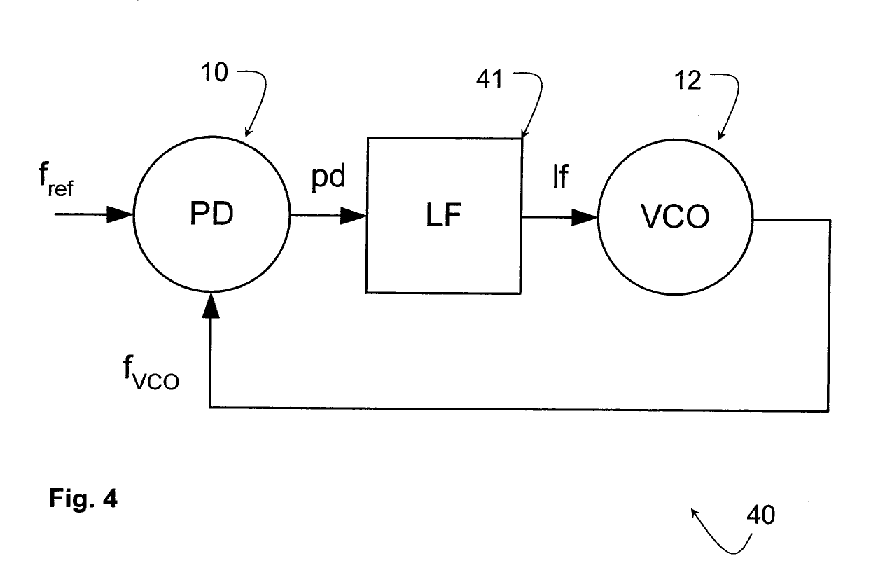

FIG. 4 shows a conventional phase detector (PD) 10 as a part of a PLL 40. According to FIG. 4 the output signal of the phase detector 10 is pd, and pd is subsequently conveyed to the following loop control component 41. The input signals of the phase detector of FIG. 4, represented by their specific frequencies, are f_{ref} and f_{vcc} corresponding to the above-mentioned signals, namely the reference signal and the local signal to be controlled. The local signal corresponds to the output signal of a voltage controlled oscillator (VCO) 12. The reference signal f_{ref} corresponds to the signal which is used as a basis signal for the local signal.

There are numerous different kinds of phase detectors in the art. It is possible to implement a phase detector with a trivial EXOR-Gate or a complex circuit comprising flip flop gates or the like. In the following a digital phase detector in the form of a bang-bang detector (BBD) is used, wherein the bang-bang detector serves as an example embodiment for a phase detector. Other kinds of phase detectors or phase comparators, may be used. Further, other circuitry that is adapted to deliver information about a phase relationship between two input signals can be used. It should be understood by those skilled in the art of circuit design that different circuitries or circuits respectively can be used to obtain information about phase relationships between two or even more signals.

Basically, the bang-bang phase detector is a binary phase detector which can be easily produced in comparison with other phase detectors. One disadvantage of the bang-bang phase detector is the negative impact on the system behavior.

Depending on the high-frequency jitter of the reference and VCO signals the bang-bang phase detector has a gain which is hardly controllable and not constant in the working range of the phase detector. Thus, the loop bandwidth of the whole system is difficult to control, and the system may even become unstable in certain ranges which leads to an unwanted jittering of the VCO signal.

Fundamentally, a bang-bang detector delivers information about phase relationships or shifts between signals but no information about the phase shift amount. Bang-bang phase detectors, also referred to as “binary” or “up/down” phase detectors, output an indication of the phase of the incoming signal relative to the local oscillator signal (VCO or DCO signal) using an up and down signal. The up and down signal has no information on how far the phase of the VCO signal differs from the incoming signal.

An aspect of an embodiment of the present invention has the ability to deal with the poor output of the bang-bang phase detector.

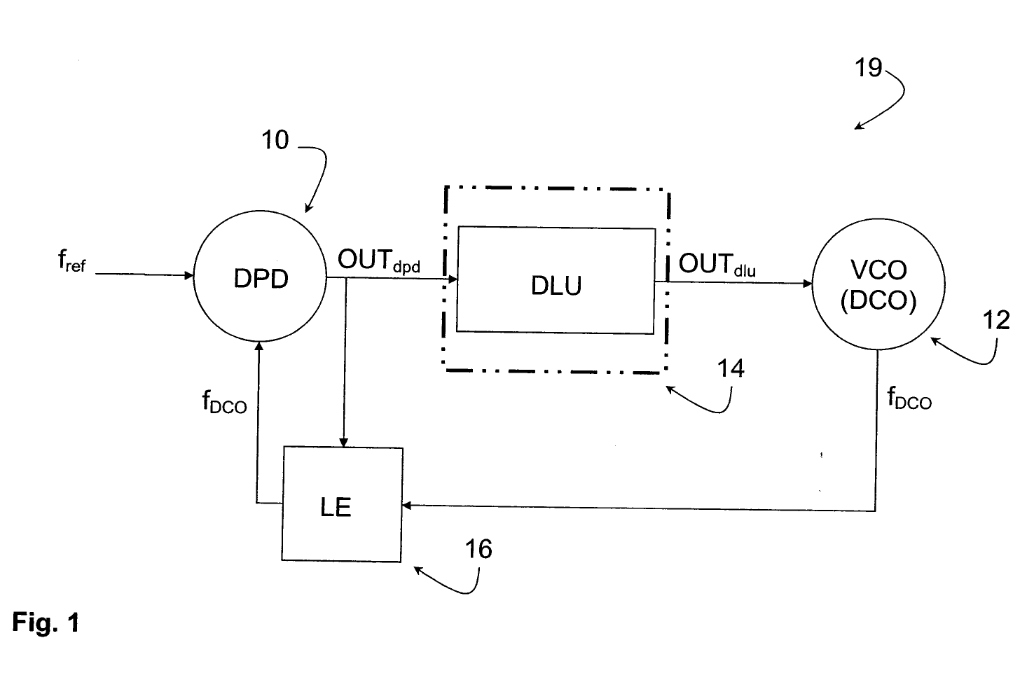

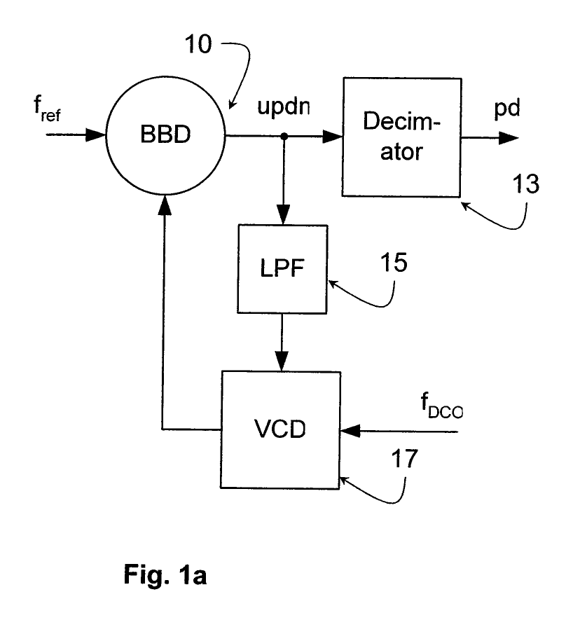

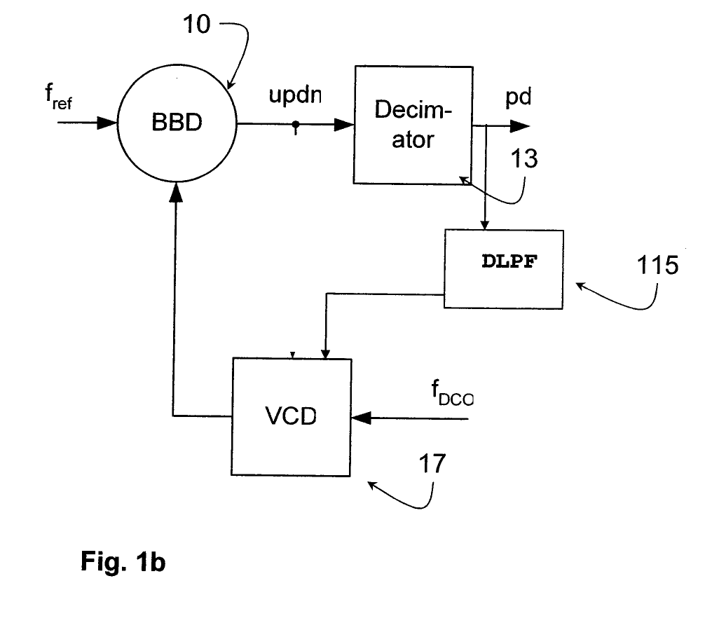

The structure of a phase-locked loop 19 may be derived based on FIG. 4 by replacing all main analogue components with digital components as shown in FIG. 1. In this case, the phase detector PD 10 can be replaced with a digital phase detector (DPD). As mentioned above f_{ref} and F_{DCO} are analogue signals, which are now compared in the digital phase detector DPD.

According to an embodiment of the present invention the DPD provides a binary word representing the phase difference or shift of f_{DCO} with respect to f_{ref}. The digital output signal of the phase detector 10 is given to a loop filter 41, for instance, which subsequently calculates the digital tuning word lf or OUT_lfu, respectively for the digitally controlled oscillator DCO. As previously mentioned this straightforward implementation of a digital system or PLL 19, respectively may lead to a non-linear and thus undesired behaviour.

With reference to FIG. 1, an embodiment of a PLL 19 according to the present invention is shown. According to this embodiment the PLL 19 comprises a digital phase detector DPD 10, a digital loop device or unit, respectively DLU 14, an oscillator VCO/DCO 12 and a loop or loop element, respectively 16. The oscillator 12 may be a digital controlled oscillator DCO but a voltage controlled oscillator VCO is also conceivable.

The DPD 10 receives two analog signals f_{ref} and f_{DCO}, wherein each of the signals has a phase and amplitude. The DPD 10 compares the phases of the corresponding signals and provides the following circuit components with information about the phasing or phase of the corresponding input signals to each other.

It is feasible that the DPD 10 will receive more than one reference signal and/or more than one oscillator signal, but generally the DPD 10 will compare the phasing of two input signals. If the DPD receives more than one reference signal it is necessary that a suitable component or module will select one reference signal for further processing. The selecting component may be a multiplexer (not shown) or the like and it may be embedded within the DPD, but an external implementation is also feasible. The same conclusions are valid for more than one oscillator signal as well. Generally, a suitable implementation of a component within or outside the DPD 10 is needed which is adapted to deal with several input signals.

According to this embodiment the output signal of the DPD 10 in FIG. 1 is referenced by OUT_{dpd}, and the signal comprises, as aforementioned, information about the phasing of the corresponding input signals. The two analog input signals f_{ref} and f_{DCO} are processed within the DPD 10 and the output signal OUT_{dpd} corresponds to a digital or quasi-digital signal, respectively that is directly used as a tuning or control signal for the DLU 14.

Further, the DLU 14 may use the control signal OUT_{dpd} to determine the control signal of the oscillator part of the PLL 19 of this embodiment. The control signal is referenced to OUT_{dlu} in FIG. 1 and the signal represents a pure digital signal processed and calculated by the DLU 14. According to the embodiment of FIG. 1 the DLU 14 directly receives the output signal of the phase detector 10 without any preprocessing steps, like for instance an A/D (analogue to digital) conversion or the like. The oscillator 12 of the present embodiment may be implemented as a pure digital controlled oscillator DCO but other implementations are feasible as well.

It should be noted that the term “digitally controlled oscillator” has also been used to describe the combination of a voltage-controlled oscillator driven by a control signal from a digital-to-analog converter. A person skilled in the art would appreciate that each arrangement which performs the objective of an oscillator may be used as well.

According to the present embodiment the PLL is equipped with a loop 16, which receives on the first input side the output signal OUT_{dpd} of the digital phase detector DPD 10. Thus the loop 16 receives the quasi-digital signal OUT_{dpd}. The second input of the loop 16 receives the output signal f_{DCO} of the digital controlled oscillator DCO 12 in accordance with this preferred embodiment. However, the loop 16 indirectly controls the output signal of the oscillator DCO because of the recursive implementation of the loop 16 according to this embodiment. If the phasing between the oscillator signal f_{DCO} and the reference signal f_{ref} drifts apart, the loop 16 is enabled to adapt the delay of the oscillator signal f_{DCO} on the output side. Hence, by controlling the signal delay within the DLL 16 an automatic control of the signal phase is provided.

Since the loop 16 receives on the first input side the phasing information signal output by the DPD 10 and on the second side the oscillator signal f_{DCO} the loop 16 automatically adapts the oscillator signal and thus unwanted clock skewing is avoided. The clock skewing effect is avoided because the oscillator signal is controlled to correspond in phase with the reference signal f_{ref}. Generally, the PLL in accordance with an embodiment of the present invention may be used within a complex circuit for generating reliable and fixed oscillator signals. In the following a detailed description of the graphically emphasized components loop 16 and DLU 14 of FIG. 1 is provided.

According to one embodiment the loop 16 and the DPD 10 form a linear phase detector. The DPD 10 may be a bang-bang phase detector or generally a binary phase detector.

FIG. 1a illustrates in detail the loop 16 and a decimator 13 of the DLU 14 according to one embodiment. It is also conceivable that the decimator is separately implemented. However the detector 10, the loop 16 and the decimator are forming according to an embodiment of the invention a linear digital phase detector. In this embodiment the detector 10 is in form of a bang-bang detector BBD. The BBD operates as a binary phase detector. As aforementioned, the sequence of up and/or down pulses updn or OUT_dpd, respectively are passed on one side to the decimator 13 and on the other side to the loop 16, that is to the low pass filter (LPF) 15.

In this embodiment, the DCO signal f_{DCO} from the oscillator DCO 12 is delayed by a voltage controlled delay stage VCD 17 and is subsequently directed to a bang-bang phase detector BBD 10 that compares the phasing of this delayed signal with the reference signal f_{ref}. The oscillator signal is processed within the VCD 17 resulting in a locked oscillator signal that is conveyed to the phase detector 10.

The low pass filtered signal may be used as a control signal for the voltage controlled delay stage 17 and on the other hand the sequence of up and down pulses updn may be directly conveyed to the DLU 14. The decimator 13 that may be a part of the DLU 14 directly receives the digital sequence of up and down pulses updn and converts it to a corresponding digital word. However, the decimator 13 generally operates as a serial to parallel converter generating the digital control word pd.

According to an embodiment a phase detector may be replaced by a delay locked loop DLL and a decimator. The DLL embodies a binary phase detector (or bang-bang phase detector) BPD 10, a filter 15 for instance a low pass filter LPF, and a voltage-controlled delay element VCD 17. The DLL tracks the phase of reference signal by controlling the delay of VCD via the filter 15.

Accordingly, the pulse sequence updn is conveyed to a decimator 13 which generates a digital parallel word from the pulse sequence, whereby the word reflects the number of ones in the sequence. If, e.g., the decimation factor is 8, the sequence [0100 0100] would be transformed into the hexadecimal word 0x2, the sequence [0101 0101] into the word 0x4, the sequency [1101 1101] into the word 0x6 etc.

Thus, the DLL and decimator form a linear digital phase detector and the digital word from the decimator may be used as input for the digital loop filter 14 within the PLL for instance.

Additionally, the digital output word of the loop filter 14 may be used as a control word for the digitally controlled oscillator DCO 12. Of course, a digital-to-analog converter can be used together with a conventional VCO 12.

Consequently, the bang-bang detector 10 may deliver a sequence of pulses with a frequency f_{ref}. On the other hand, the decimator 13 output pd delivers digital words at a rate of f_{ref}/N if the decimator 13 evaluates N comparisons of the bang-bang detector 10 for each digital word.

The delay time of the voltage controlled delay block 17 changes by Δτ if the phase detector 10 changes from generating steady up pulses for instance [1111] to steady down pulses for instance [0000]. Herein, the time delay difference corresponds to a phase difference of:
ΔΦ=2πf_{ref}Δτ. (1)

The output word pd changes by N in this case. It should be noted that averaging a number of N samples in the decimator 13 yields to a number of N+1 digital states because the phase detector can generate 0, 1, 2, . . . , or N ones. Hence the effective phase detector constant which is defined as the quotient of the signal change at the output and the input is:

$${K}_{d} = \frac{N}{Δ Φ} . \qquad ( 2 )$$

The following describes the functionality of the loop 16 in more detail based on two examples. Assumed that the phase difference between the DCO output and the reference signal may be 0. Further let the conversion factor of the voltage-controlled delay element be 2π/V and the delay τ=0 at an input voltage of 0.5 V. (The delay is of course always positive but here is treated relative to a fixed delay of the reference signal, so that positive and negative values are possible.) Further, let the binary phase detector 10 output levels be 0 V for “down” and 1 V for “up”. The filter 15 is a simple smoothing low-pass with a transfer function of 1 in the pass band. The delay-locked loop including the phase detector 10 and the loop 16 will track the VCO phase to the reference signal and add no delay. The phase detector issues a pulse stream with equally distributed “up” und “down” impulses, i.e. (01010101) . . . , so that a low-pass filtered average voltage of 0.5 V goes to the voltage-controlled delay element as mentioned above.

Assumed that the phase difference between the DCO output and the reference signal may be π/4. Once more, the delay-locked loop will track the VCO phase and add a phase shift of π/4. The phase detector 10 has to issue a pulse stream with an average dc level which causes a delay of π/4 in the VCD, i.e. 0.5 V+(π/4)/(2π/V)=0.625 V. This is achieved by a sequence of 5 times “up” and 3 times “down”, e.g. (11011010).

FIG. 1b illustrates a linear phase detector according to one embodiment of the present invention. Comparing the embodiment of FIG. 1b with the embodiment of FIG. 1a it becomes clear that the low pass filter LPF is replaced with a digital low pass filter DLPF 115. According to this embodiment, the input of the DLPF 115 is connected to the output of the decimator 13. Thus, the DLPF 115 receives a digital signal or a digital word, respectively which is to be processed within the DLPF 115.

The DLPF 115 delivers a digital control signal which may be used a control signal for the VCD 17. According to this embodiment of the linear phase detector the VCD 17 is implemented as a digital VCD adapted to be controlled by the digital signal from the DLPF 115. As aforementioned the digital VCD 17 may be replaced with a digital current controlled delay which is also adapted to receive the digital input signal delivered by the DLPF 115.

The other elements of the embodiment according to FIG. 1b are connected in the same way as illustrated with reference to FIG. 1a.

It should be noted that the voltage controlled delay VCD may be implemented as a current controlled delay, for instance. It should be understood by those skilled in the art of circuit design that different circuitries or circuits respectively can be used which performs the functionality of a voltage controlled delay, for instance.

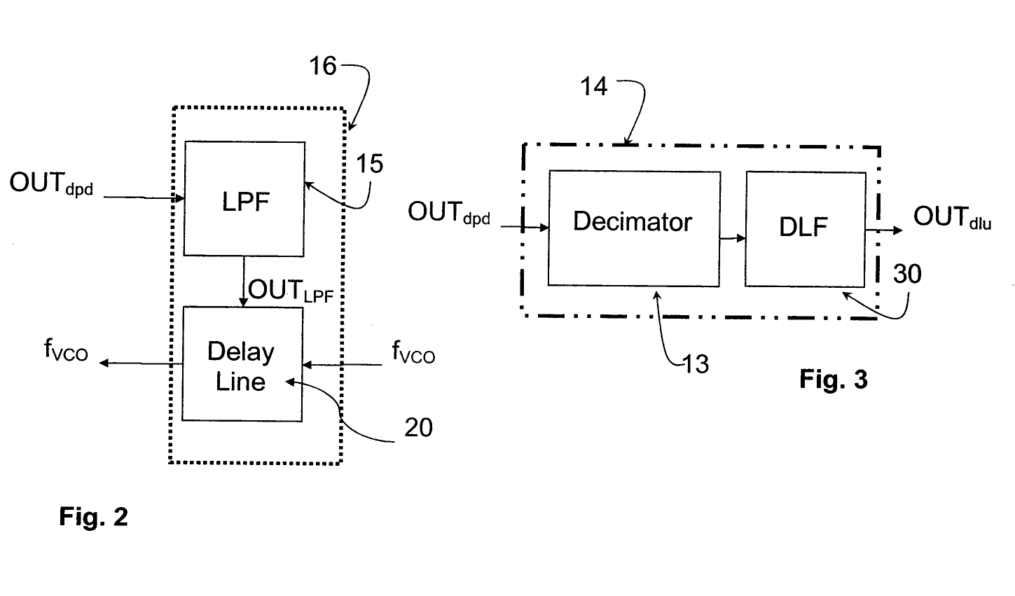

FIG. 2 shows a detailed embodiment of the loop 16 already introduced with reference to FIG. 1. The loop arrangement 16 of this embodiment comprises two components: a low pass filter (LPF) 15 and a delay line 20. The main objective of the delay line component 20 is to apply a controlled time delay on the propagation time of the oscillator signal trough the loop path. The delay line component 20 is controllable and the propagation time may be controlled by means of the signal that is generated at the output of the low pass filter 15. However, the control signal of the delay line component 20 according to the present embodiment corresponds to the low pass filtered output signal OUT_{LPF} of the digital phase detector 10, namely OUT_{dpd} which is illustrated in FIG. 1. According to this embodiment, the sequence of up and down pulses updn provided by the digital phase detector 10 are issued to the low pass filter unit 15. The quasi-digital input sequence of the LPF 15 will be however transformed within the LPF unit 15 into an analog signal. The analog signal OUT_{lpf} provided by the low pass unit 15 serves as control input for the delay line 20. The delay line may be in form of a voltage controlled delay line but also other arrangements or circuits are feasible.

It is conceivable that the low pass filter component 15 may be in form of another module enabled to provide low-pass functionality.

FIG. 3 shows an embodiment of the digital loop filter unit 14 according to FIG. 1. As aforementioned, the output of the digital phase detector OUT_{dpd} can correspond to a sequence of up and down pulses updn corresponding to the phasing between the reference signal f_{ref} and the oscillator signal f_{DCO}.

According to this embodiment the digital signal or the sequence of up and down pulses updn, respectively is directly conveyed to a decimator 13 that is part of the digital loop filter unit 14. The decimator 13 converts the sequence of up and down pulses into a digital word. That is the sequence of samples or up and down pulses respectively is converted into a parallel word that is to be processed by the digital loop filter (DLF) 30.

The digital word is a pure digital signal representing a sequence of ones and zeros which is directed to a digital loop filter 30 that in turn determines the control signal of the digital controlled oscillator 12.

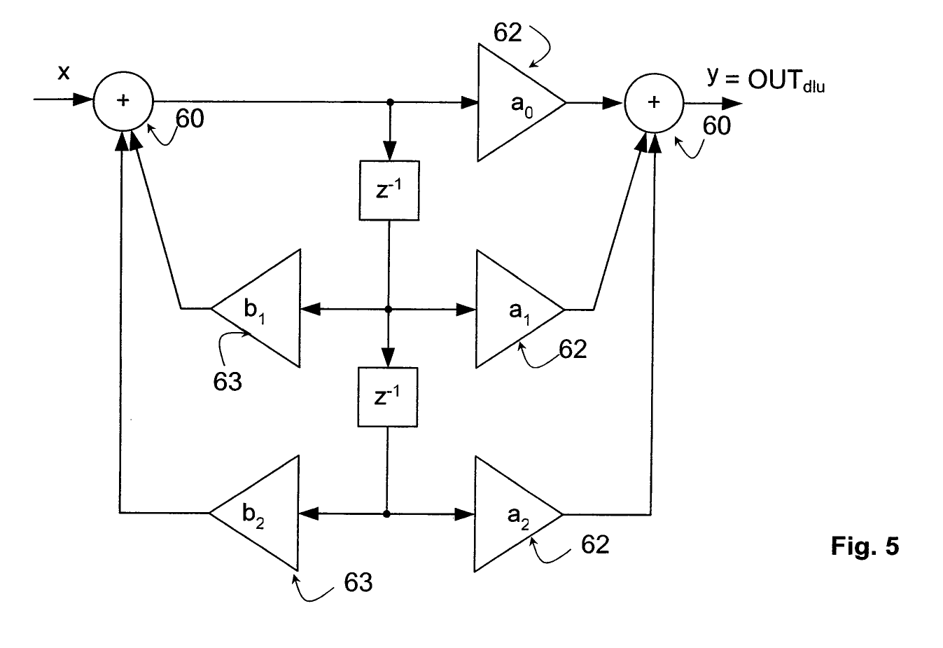

One possible digital filter structure for the digital loop filter 30 is shown in FIG. 5.

FIG. 5 shows a structure of a digital loop filter 30 according to one embodiment of the present invention. In addition to the filter coefficients a₀ to a₂ 62 and b₁, b₂ 63 two delay elements referred as z⁻¹ 65 and two adders 60 are provided. The delay elements are known in the art and they correspond to a time delay of one digital sample.

The input signal x of the digital filter may be connected to the output of the decimator 13 corresponding to the digital word and correspondingly the output signal y may be directly used as a control signal of the digitally controlled oscillator 12. According to one embodiment the output y corresponds to the output signal OUT_{dlu} of the digital loop filter unit 14, that is illustrated with reference to FIG. 1.

Even though the invention is described above with reference to embodiments according to the accompanying drawings, it is clear that the invention is not restricted thereto but it can be modified in several ways within the scope of the appended claims.

What is claimed is:

1. A circuit generating a phase difference signal between a reference signal and an oscillator signal, comprising:
a delay locked loop comprising a binary phase detector which generates a binary phase detector signal; and
a decimator receiving said binary phase detector signal; and
wherein said decimator generates said phase difference signal.

2. A circuit according to claim 1, wherein said binary phase detector receives said reference signal and a delayed oscillator signal.

3. A circuit according to claim 1, wherein said digital locked loop comprises a filter for processing said binary phase signal and a voltage controlled delay element receiving said filtered phase signal generating said delayed oscillator signal.

4. A circuit according to claim 3, wherein said filter is a low pass filter.

5. A circuit according to claim 2, wherein said delayed oscillator signal is controlled by said voltage controlled delay element.

6. A circuit according to claim 1, wherein said binary signal corresponds to a sequence of up and down pulses.

7. A circuit according to claim 1, wherein said binary phase detector is a non-linear phase detector.

8. A circuit according to claim 1, wherein said phase difference signal is a digital word.

9. A circuit according to claim 1, wherein said binary phase detector is a bang-bang phase detector.

10. A circuit according to claim 1, wherein said circuit is an integrated linear phase detector.

11. An integrated circuit, comprising:
a linear phase detector receiving a reference signal and an oscillator signal, said linear phase detector generating a phase relationship signal based on said reference signal and said oscillator signal;
a digital loop filter receiving said phase relationship signal and generating a digital control signal; and
a digital controlled oscillator receiving said digital control signal and generating said oscillator signal.

12. An integrated circuit according to claim 11, said linear phase detector, comprising:
a delay locked loop comprising a binary phase detector which generates a binary phase detector signal; and
a decimator receiving said binary phase detector signal; and
wherein said decimator generates said phase relationship signal.

13. An integrated circuit according to claim 11, wherein said generated phase relationship signal is a digital signal.

14. An integrated circuit according to claim 11, wherein said binary phase detector generates a sequence of up and down pulses according to phase differences of input signals.

15. An integrated circuit according to claim 14, wherein the input signals correspond to said reference signal and said locked oscillator signal.

16. An integrated circuit according to claim 11, wherein said decimator directly receives said binary phase signal.

17. An integrated circuit according to claim 11, wherein said decimator generates a digital word for controlling said digital loop filter.

18. An integrated circuit according to claim 12, further comprising an analogue to digital converter receiving said phase relationship signal, said converter generating an input signal for said digital loop filter unit.

19. An integrated circuit according to claim 12, wherein said digital phase detector is a bang-bang phase detector.

20. An integrated circuit according to claim 12, wherein said loop comprises:
a low pass filter receiving said binary phase signal, said low pass filter generating a low pass filtered signal; and
a delay line for processing said oscillator signal, said delay line generating said locked loop signal.

21. An integrated circuit according to claim 20, wherein said delay line generates said locked loop signal based on said low pass filtered signal.

22. An integrated circuit according to claim 20, wherein said digital controlled oscillator generates said oscillator signal based on said digital control signal.

23. An integrated circuit according to claim 20, further comprising a multiplexer for selecting a reference signal.

24. An integrated circuit according to claim 23, further comprising a second multiplexer for selecting a second signal, said second signal corresponding to said oscillator signal.

25. An integrated circuit according to claim 20, wherein said digital controlled oscillator further comprises a tuning component tuning the phase of said oscillator signal.

26. A method for controlling an oscillator signal with an integrated circuit, comprising:
receiving a reference signal and an oscillator signal;
generating a phase relationship signal based on said reference signal and said oscillator signal;
filtering said generated phase relationship signal to produce a filtered phase relationship signal; and
generating an oscillator signal using said filtered signal.

27. A method according to claim 26, further comprising a low pass filtering step of said phase relationship signal.

28. A method according to claim 26, further comprising directly using said generated phase relationship signal for said filtering step.

29. A method according to claim 26, further comprising transforming said phase relationship signal into a binary word by means of a decimator, wherein said transforming step is provided by omitting a previously performed analogue to digital transforming step.

30. An integrated circuit, comprising:
a phase detector receiving a first signal and a second signal, said phase detector generating a fifth signal based on said first signal and said second signal;
a loop filter unit receiving said fifth signal and generating a third signal;
a controlled oscillator receiving said third signal and generating a fourth signal; and
a loop receiving said fourth signal and said fifth signal, said loop generating said second signal.

31. An integrated circuit according to claim 30, wherein said first signal is a reference signal.

32. An integrated circuit according to claim 30, wherein said phase detector is a digital phase detector.

33. An integrated circuit according to claim 30, wherein said second signal is a locked oscillator signal.

34. An integrated circuit according to claim 30, wherein said third signal is a digital control signal.

35. An integrated circuit according to claim 30, wherein said fourth signal is an oscillator signal.

36. An integrated circuit according to claim 30, wherein said fifth signal is a phase relationship signal.

37. An integrated circuit according to claim 36, wherein said phase relationship signal is a digital signal.

38. An integrated circuit according to claim 30, wherein said loop filter unit comprises:
a decimator receiving said fifth signal, and said decimator generates a digital loop filter signal; and
a loop filter receiving said digital loop filter signal, and said loop filter generates said third signal.

39. An integrated circuit according to claim 30, wherein said loop comprises:
a low pass filter receiving said fifth signal, said low pass filter generating a low pass filtered signal; and
a delay line for processing said oscillator signal, said delay line generating said second signal.

40. An integrated circuit according to claim 30, wherein said delay line is a voltage controlled delay component.

41. An integrated circuit, comprising:
means for receiving a reference signal and a locked oscillator signal;
means for generating a phase relationship signal based on said reference signal and said locked oscillator signal;
means for filtering said generated phase relationship signal to produce a filtered phase relationship signal;
means for generating an oscillator signal using said filtered signal;
means for processing said oscillator signal.

42. An integrated circuit according to claim 41, further comprising low pass filtering means.

43. An integrated circuit according to claim 41, further comprising means for using said generated phase relationship signal.

44. An integrated circuit according to claim 41, further comprising means for transforming said phase relationship signal into a binary word.
